(19) United States
(12) Patent Application Publication
(10) Pub. No.: US 2022/0149593 A1
(43) Pub. Date: May 12, 2022

(54) HIGH FREQUENCY CURRENT MODULATION DEVICE CONTROLLER

(71) Applicant: DAYLIGHT SOLUTIONS, INC., San Diego, CA (US)

(72) Inventors: Ronald Kevin Arp, Ramona, CA (US); Timothy Day, San Diego, CA (US)

(21) Appl. No.: 17/519,218

(22) Filed: Nov. 4, 2021

Related U.S. Application Data
(60) Provisional application No. 63/110,646, filed on Nov. 6, 2020.

(51) Int. Cl. H01S 5/042; H01S 5/34; H01S 5/024; H01S 3/091

(52) U.S. Cl. CPC H01S 5/0427; H01S 3/0912; H01S 5/02469; H01S 5/3402

(57) ABSTRACT

A device controller (16) for directing a drive current (12A) to a device (12) includes a current driven power source (40) that is electrically connected to the device (12); and a current adjuster (22) electrically connected to the power source (40) in parallel to the device (12). The current adjuster (22) selectively adjusts the drive current (12A) directed to the device (12). For a laser (12), the current adjuster (22) can adjust the drive current (12A) to modulate a center wavelength of an illumination beam (20) generated by the laser (12).

### RELATED APPLICATION

The present application claims priority on U.S. Provisional Application No. 63/110,646 filed on Nov. 6, 2020, and entitled “HIGH FREQUENCY CURRENT MODULATION DEVICE CONTROLLER”. As far as permitted, the contents of U.S. Provisional Application No. 63/110,646 are incorporated herein.

### BACKGROUND

Semiconductor devices such as quantum cascade devices, interband cascade devices, and light-emitting diodes can be turned into tunable lasers through a variety of means. For example, a tunable laser can be an external cavity laser that includes the semiconductor device, and a tunable wavelength selective element that is spaced apart from the semiconductor device. In this design, the semiconductor device is the laser gain medium, and the wavelength selective element is selectively tuned to adjust a center optical wavelength of an illumination beam generated by the tunable laser.

These external cavity lasers are often used in applications where it is desired to provide an illumination beam having a center optical wavelength that is tuned over time over a tunable range while recording the response of some sample as a function of the changing optical wavelength of the illumination beam. In these applications, the quality of the response will depend upon the accuracy of the tuning of the laser. As a result thereof, there is constant search to improve the accuracy of the tuning of the laser.

### SUMMARY

In one implementation, the present invention is directed to a device controller for directing a drive current to a device. The device controller can include a current driven power source that is electrically connected to the device; and a current adjuster electrically connected to the power source in parallel to the device. The current adjuster selectively adjusts the drive current directed to the device. As provided herein, for a laser device, the amount of drive current to the laser influences a center wavelength of an illumination beam generated by the laser. Thus, the device controller can rapidly, accurately, and selectively control, tune, and/or modulate the center wavelength of illumination beam. As non-exclusive examples, the device controller can rapidly modulate the drive current (i) to effectively broaden a linewidth of the illumination beam; and/or (ii) to modulate the wavelength in a controlled fashion.

The power source can generate a source current, and the current adjuster can selectively drain current to selectively adjust the drive current to the device. The power source can include a pulse generator and the power source can direct current to the device in a pulsed fashion.

The invention can be directed to a laser assembly that includes a laser, and the device controller can direct the drive current to the laser to generate an illumination beam. The laser can include a quantum cascade gain medium, and the current adjuster can selectively adjust the drive current to the gain medium to selectively adjust (modulate) the wavelength of the illumination beam. Additionally, or alternatively, the current adjuster can selectively adjust the drive current to the gain medium to effectively adjust a linewidth of the illumination beam that otherwise has a relatively narrow linewidth. Additionally, or alternatively, the current adjuster can selectively adjust the drive current to the gain medium to modulate the wavelength.

Additionally, or alternatively, the laser can include a thermal mount that is thermally connected to the quantum cascade gain medium, and a thermal controller that controls the temperature of the thermal mount. The thermal mount can also be thermally connected to the current adjuster.

Additionally, or alternatively, the laser can include a wavelength selective element that is controllable to make relatively coarse adjustments to a wavelength of the illumination beam. In this design, the current adjuster selectively adjusts the drive current to the gain medium to finely adjust the wavelength of the illumination beam.

In another implementation, a laser assembly for generating an illumination beam includes: a quantum cascade gain medium that generates the illumination beam; a wavelength selective element that is controllable to make relatively coarse adjustments to a wavelength of the illumination beam; and a device controller for directing a drive current to the gain medium. The device controller can include (i) a current driven power source that is electrically connected to the gain medium, and (ii) a current adjuster electrically connected to the power source in parallel to the gain medium. The current adjuster is controllable to selectively adjust the drive current directed to the gain medium to finely adjust the wavelength of the illumination beam.

In yet another implementation, a method for directing a drive current to a device includes: electrically connecting a current driven power source to the device; electrically connecting a current adjuster to the power source in parallel to the device; and selectively adjusting the drive current directed to the device with the current adjuster.

### BRIEF DESCRIPTION OF THE DRAWINGS

The novel features of this invention, as well as the invention itself, both as to its structure and its operation, will be best understood from the accompanying drawings, taken in conjunction with the accompanying description, in which similar reference characters refer to similar parts, and in which:

FIG. 1 is a simplified schematic of a device and a control system including a device controller for controlling the operation of the device;

FIG. 2 is a simplified schematic of the device and a portion of the device controller from FIG. 1;

FIG. 3 is a graph that illustrates the relationship of current versus voltage for a quantum cascade gain medium;

FIG. 4 is a simplified schematic of a non-exclusive implementation of the device controller; and

FIG. 5 is a simplified schematic of another implementation of an assembly.

### DESCRIPTION

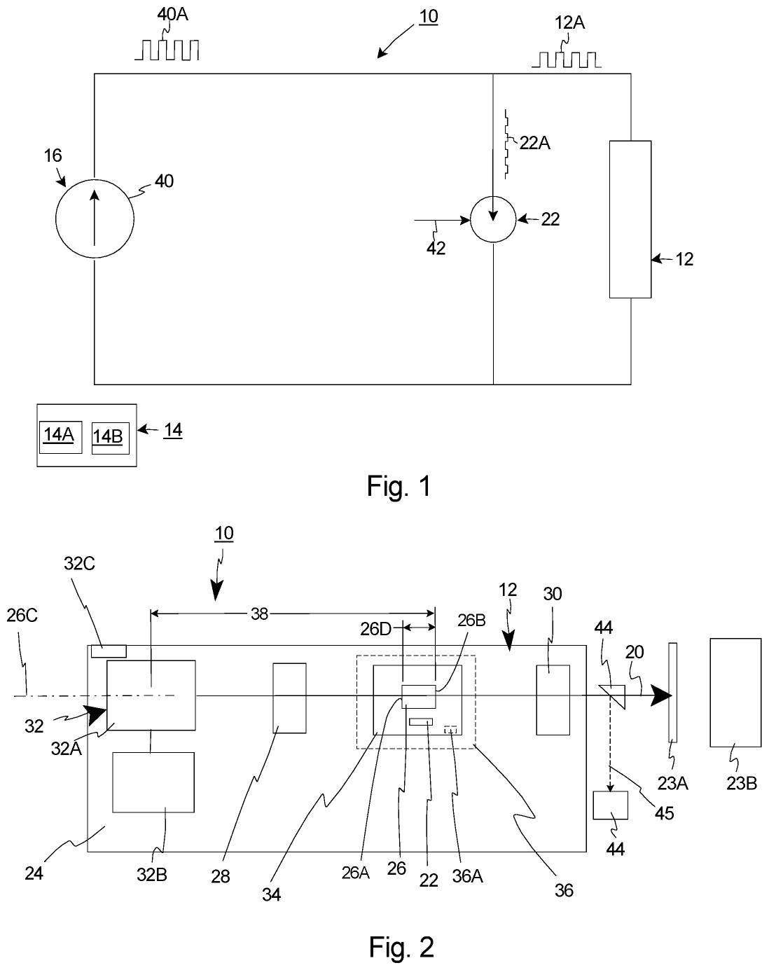

FIG. 1 is a simplified schematic illustration of an assembly 10 including a device 12 (illustrated as a box), and a control system 14 (illustrated as a box) that includes a device controller 16 for controlling the operation of the device 12. The design of the assembly 10 and each of the components can be varied pursuant to the teachings provided herein. In one non-exclusive implementation, the assembly 10 is a laser assembly and the device 12 includes a laser that generates an illumination beam 20 (illustrated in FIG. 2). As an overview, the device controller 16 is uniquely designed to include a current adjuster 22 that is controlled to rapidly, accurately, and selectively control, tune, and/or modulate a drive current 12A (illustrated with a pulsed signal) directed to the laser 12. As provided herein, the amount of drive current 12A to the laser 12 influences a wavelength of illumination beam 20. Thus, the device controller 16 can rapidly, accurately, and selectively control, tune, and/or modulate the wavelength of illumination beam 20. As non-exclusive examples, the device controller 16 can rapidly modulate the drive current (i) to effectively broaden a linewidth of the illumination beam 20; and/or (ii) to modulate wavelength in a controlled fashion.

FIG. 2 is a simplified schematic of a portion of the laser assembly 10 including the laser 12 and the current adjuster 22 (illustrated as a box). In the non-exclusive implementation of FIG. 2, the laser assembly 10 is tunable and generates the illumination beam 20 (illustrated as a line with an arrow) having a center wavelength that is varied (“tuned”) over time over a tunable range. Stated in another fashion, the laser 12 can be tuned to different center wavelengths over time as necessary.

The laser 12 can be used in a variety of different applications. As non-exclusive examples, the laser assembly 10 can be used for imaging, locating, detecting, and/or identifying a substance, e.g. a gas or a trace element, analyzing a sample, and/or other industrial or testing applications. For example, the laser assembly 10 can be used as part of a spectroscopy system, a microscope or another type of system.

The simplified, non-exclusive implementation of FIG. 2 includes a sample 23A (illustrated as a box) and a detector 23B (illustrated as a box). With this design, the illumination beam 20 is directed at the sample 23A, and the detector 23B records the response as a function of the changing wavelength of the illumination beam 20 as the laser 12 is tuned over at least a portion of the tunable range. The type of sample 23A that is spectrally analyzed can vary. As non-exclusive examples, the sample 23A can be a liquid, a complex mixture of multiple liquids, or a complex mixture of liquids, dissolved chemicals, and/or solids. The detector 23B is operable in (sensitive to) the wavelengths of the tunable range. For example, the detector 23B can include a two-dimensional sensor array.

In FIG. 2, the laser assembly 10 includes a single, external cavity laser 12 having a Littrow configuration. Alternatively, the laser assembly 10 can include multiple individually tunable lasers that each span a different portion of a desired spectral range. In this example, when multiple lasers are used, each laser can generate a different portion of the desired spectral range, with slight overlapping of the wavelengths generated to allow for calibration of the lasers and better fidelity. A description of a system that includes multiple individual lasers is described in U.S. Pat. No. 9,086,375, entitled “Laser Source With A Large Spectral Range”. As far as permitted, the contents of U.S. Pat. No. 9,086,375 are incorporated herein by reference.

The tunable range and the design of the laser 12 can be varied. In alternative, non-exclusive examples, the size of the tunable (wavelength) range can be at least approximately 2, 3, 4, 5, 8, 10, 15, 18, 20 or 25 micrometers. In additional, alternative, non-exclusive examples, the size of the tunable (wavenumber) range can be at least approximately 50, 100, 200, 300, 400, 500, 1000, 2000, 3000, 4000, 4500, or 5000 cm-1 wavenumbers. However, the size of the tunable range can larger or smaller than these amounts.

In certain non-exclusive embodiments, the laser 12 is a tunable mid-infrared light source that directly generates and emits a substantially temporally coherent illumination beam 20 having a center wavelength that is in the mid-infrared (“MIR”) range. In this example, the tunable range can be the MIR range or a portion thereof. As used herein, the term “MIR range” shall mean and include the spectral region or spectral band of between approximately five thousand to five hundred wavenumbers (5000-500 cm⁻¹), or approximately two and twenty micrometers (2-20 μm) in wavelength. The mid-infrared range is particularly useful to spectroscopically interrogate a sample 23A since many samples 23A are comprised of molecules or groups of molecules that have fundamental vibrational modes in the MIR range, and thus present strong, unique absorption signatures within the MIR range.

In another embodiment, the tunable range is only a portion of the MIR range. As alternative, non-exclusive examples, the tunable range can be the wavelength range of approximately 2-10 micrometers; 10-20 micrometers; 5-15 micrometers; 5-10 micrometers; 10-15 micrometers; or 15-20 micrometers. In additional, alternative non-exclusive examples, the tunable range can be the wavenumber range of approximately 500-5000 cm-1; 500-1000 cm-1; 1000-1500 cm-1; 1500-2000 cm-1; 2000-2500 cm-1; 2500-3000 cm-1; 3000-3500 cm-1; 3500-4000 cm-1; 4000-4500 cm-1; or 4500-5000 cm-1.

Still alternatively, the tunable laser 12 can be designed to generate the illumination beam 20 having wavelengths that are greater than or less than the MIR range. For example, the laser 12 can be designed to generate the illumination beam 20 having a center wavelength in another portion of the infrared range or in the visible or ultra-violet range.

In the non-exclusive implementation of FIG. 2, the laser 12 includes (i) a laser frame 24, (ii) a gain medium 26, (iii) a cavity optical assembly 28, (iv) an output optical assembly 30, (v) a tunable wavelength selective element 32, (vi) a thermal mount 34, and (vii) a thermal controller 36 (illustrated in phantom). The design of each of these components can be varied.

It should be noted that in this design, the tunable wavelength selective element 32 is controlled to make relatively coarse (and relatively slow) adjustments to the center wavelength over the relatively large tunable range; while the current adjuster 22 is controlled to make relatively fine (and relatively fast) adjustments to the center wavelength over a relatively small range.

As used herein, (i) “relatively coarse adjustments” shall mean step sizes that are greater than 0.1 wavenumbers, (ii) “relatively fine adjustments” shall mean sizes that are less than 0.1 wavenumbers, (iii) “relatively slow adjustments” shall mean longer than ten millisecond; and (iv) “relatively fast adjustments” shall mean shorter than ten millisecond. As alternative, non-exclusive examples, the current adjuster 22 can be controlled to make fine adjustments of approximately 0.1, 0.01, 0.005, 0.003, or 0.001 wavenumbers.

The laser frame 24 is rigid, supports one or more of the other components of the laser 12, and maintains these components in alignment.

The gain medium 26 generates the illumination beam 20. The design of the gain medium 26 can be varied pursuant to the teachings provided herein. In one, non-exclusive embodiment, the gain medium 26 directly emits the illumination beam 20 without any frequency conversion. As a non-exclusive example, the gain medium 26 can be a semiconductor type laser. More specifically, in certain embodiments, the gain medium 26 is a Quantum Cascade (QC) gain medium, or an Interband Cascade (IC) gain medium.

In FIG. 2, the gain medium 26 includes (i) a first facet 26A that faces the cavity optical assembly 28 and the wavelength selective element 32, and (ii) a second facet 26B that faces the output optical assembly 30. In this embodiment, the gain medium 26 emits from both facets 26A, 26B along a lasing axis 26C. Further, the gain medium 26 has a medium length 26D between the facets 26A, 26B. In one embodiment, the first facet 26A is coated with an anti-reflection (“AR”) coating and the second facet 26B is coated with a reflective coating. The AR coating allows light directed from the gain medium 26 at the first facet 26A to easily exit the gain medium 26 as a beam directed at the wavelength selective element 32; and allows the beam reflected from the wavelength selective element 32 to easily enter the gain medium 26.

The illumination beam 20 exits from the second facet 26B. The reflective coating on the second facet 26B reflects at least some of the light that is directed at the second facet 26B from the gain medium 26 back into the gain medium 26. In one non-exclusive embodiment, the AR coating can have a reflectivity of less than approximately 2 percent, and the reflective coating can have a reflectivity of between approximately 2-95 percent. In this embodiment, the reflective coating on the second facet 26B acts as an output coupler (e.g., a first end) for the external cavity.

The cavity optical assembly 28 is positioned between the gain medium 26 and the wavelength selective element 32 along the lasing axis 26C, and collimates and focuses the light that passes between these components. For example, the cavity optical assembly 28 can include a single lens or more than one lens. The lens can be an aspherical lens having an optical axis that is aligned with the lasing axis 26C. In one embodiment, to achieve the desired small size and portability, the lens has a relatively small diameter. The lens can comprise materials selected from the group of Ge, ZnSe, ZnS, Si, CaF2, BaF2 or chalcogenide glass. However, other materials may also be utilized.

The output optical assembly 30 is positioned along the lasing axis 26C. In this design, the output optical assembly 30 collimates and focuses the illumination beam 20 that exits the second facet 26B of the gain medium 26. For example, the output optical assembly 30 can include a single lens or more than one lens that are somewhat similar in design to the lens of the cavity optical assembly 28.

The wavelength selective element 32 reflects the light back to the gain medium 26, and is used to coarsely select and adjust the lasing frequency (wavelength) of the external cavity and the center optical wavelength of the illumination beam 20. Stated in another fashion, the wavelength selective element 32 is used to feed back to the gain medium 26 a relatively narrow band optical frequency which is then amplified in the gain medium 26. In this manner, the illumination beam 20 may be tuned with the wavelength selective element 32. Thus, with the external cavity arrangements disclosed herein, the wavelength selective element 32 coarsely dictates what wavelength (optical frequency) will experience the most gain and thus dominate the optical wavelength of the illumination beam 20.

A number of alternative embodiments of the wavelength selective element 32 can be utilized. In FIG. 2, the frequency selective element 32 is spaced apart from the gain medium 26 and defines a second end of the external cavity. In this embodiment, the external cavity extends from the output coupler (reflective coating) on the second facet 26B of the gain medium 26 to the wavelength selective element 32 and has a physical cavity length 38. It should be noted that in this example, an effective optical cavity length will depend on the physical cavity length 38, the index of refraction of the cavity optical assembly 28, and the index of refraction of the gain medium 26. Further, the wavelength of the illumination beam 20 will depend upon the effective optical cavity length.

In one, non-exclusive embodiment, the wavelength selective element 32 includes (i) a diffraction grating 32A, (ii) a grating mover 32B (e.g. a voice coil actuator) that selectively moves (e.g., rotates) the diffraction grating 32A to coarsely adjust the lasing wavelength (wavenumber) of the gain medium 26 and the center wavelength of the illumination beam 20, and (iii) a grating measurement system 32C. For example, the grating mover 32B can rapidly pivot the grating angle at a high rate (e.g. 30-1500 hertz) to adjust the effective optical cavity length, and the center wavelength over time through the tunable range. The position of diffraction grating 32A can be continuously monitored with the grating measurement system 32C, e.g., an optical encoder, that monitors the position of the diffraction grating 32A and provides for closed loop control of the grating mover 32B. With this design, the wavelength of the illumination beam 20 can be selectively and coarsely adjusted in a closed loop fashion throughout a desired spectral range.

Alternatively, for example, the wavelength selective element 32 can be an integrated distributed feedback grating (not shown) with electrically or thermally adjustable index of refraction, or another type of wavelength selective element 32. A discussion of the techniques for realizing the full laser tuning range from a semiconductor device can be found in M. J. Weida, D. Caffey, J. A. Rowlette, D. F. Arnone and T. Day, “Utilizing broad gain bandwidth in quantum cascade devices”, Optical Engineering 49 (11), 111120-111121-111120-111125 (2010). As far as permitted, the contents of this article are incorporated herein by reference.

The thermal mount 34 retains the gain medium 26, is in thermal communication with (and thermally connected to) the gain medium 26, and is used to maintain the desired temperature of the gain medium 26. For example, the thermal mount 34 can be made of material with a high thermal conductivity.

The thermal controller 36 is thermally connected to the thermal mount 34, and maintains the desired temperature of the thermal mount 34 and the gain medium 26. As a non-exclusive example, the thermal controller 36 can include one or more thermoelectric coolers, heaters, and/or other devices for controlling the temperature of the thermal mount 34 and the gain medium 26. The thermal controller 36 can include one or more temperature sensors 36A (illustrated as a box) for closed loop temperature control of the thermal mount 34 and/or the gain medium 26.

It should be noted that the temperature of the gain medium 26 influences the efficiency of the gain medium 26, influences the index of refraction of the gain medium 26 and the medium length 26D of the gain medium 26. Generally speaking, (i) increasing the temperature of the gain medium 26 results in an increase of the index of refraction of the gain medium 26 and an increase of the medium length 26D; and (ii) decreasing the temperature of the gain medium 26 results in a decrease of the index of refraction of the gain medium 26, and a decrease of the medium length 26D.

Further, as provided above, the index of refraction of the gain medium 26 and the medium length 26D influences the effective optical cavity length and the wavelength of the illumination beam 20. As a result thereof, (i) the effective optical cavity length will increase as the index of refraction increases, and (ii) the effective optical cavity length will decrease as the index of refraction decreases. Further, (i) the wavelength of the illumination beam 20 increases as the effective optical cavity length increases, and (ii) the wavelength of the illumination beam 20 decreases as the effective optical cavity length decreases.

As provided herein, the current adjuster 22 can finely adjust the drive current 12A to the gain medium 26 to finely adjust the temperature of the gain medium 26, the index of refraction of the gain medium 26, the effective optical cavity length, and the wavelength of the illumination beam 20. Stated in another fashion, the dynamic adjustment of the drive current 12A by the current adjuster 22 causes a dynamic change in temperature of the gain medium 26, a dynamic change in the index of refraction, a dynamic change in the effective optical cavity length, and ultimately a dynamic change in the wavelength of the illumination beam 20. As a result thereof, the current adjuster 22 can be used (e.g. like a knob) to finely and rapidly tune the wavelength within a range permitted by the wavelength selective element 32.

Referring FIGS. 1 and 2, the control system 14 controls the operation of the device 12. For example, in the tunable laser 12 design described above, the control system 14 can (i) control the device controller 16 to precisely control the drive current 12A that is directed the laser 12; (ii) control the grating mover 32B to position the grating 32A and roughly tune the center wavelength of the illumination beam 20; (iii) control the thermal controller 36 to roughly control the temperature of the thermal mount 34 and the gain medium 26; and (iv) control the current adjuster 22 of the device controller 16 to finely adjust the temperature of the gain medium 26, and finely tune (modulate) the center wavelength of the illumination beam 20. The control system 14 can include one or more processors 14A and one or more electronic storage devices 14B. The control system 14 can be a single, central processing system, or a distributed processing system.

The device controller 16 precisely controls the drive current 12A that is directed the laser 12. The design of the device controller 16 can be varied pursuant to the teachings provided herein. In the non-exclusive implementation of FIG. 1, the device controller 16 includes a current driven power source 40 that is electrically connected to the device 12; and the current adjuster 22 and the device 12 are electrically connected in parallel to the power source 40.

The current driven power source 40 generates a source current 40A (illustrated with a pulsed signal) that is directed to the rest of the circuit. The design of the power source 40 can be varied. For example, the current driven power source 40 can be an electronic circuit that delivers a constant source current 40A, or a pulsed source current 40A. In certain implementations, the power source 40 can be controlled by the control system 14 to set the properties (e.g. amplitude, frequency, and wave shape) of the generated pulsed source current 40A, The desired properties of the generated source current 40A will depend upon the desired usage of the device 12 and the assembly 10. As a non-exclusive example, the generated source current 40A can have a rectangular shaped pulse. In certain implementations, the power source 40 can includes a metal-oxide-semiconductor field-effect transistor (“MOSFET”).

A source amplitude of the source current 40A can be varied according to the needs/requirements of the device 12. As a non-exclusive examples, if the device 12 includes a Quantum Cascade gain medium 26, the power source 40 can direct the source current 40A having a source amplitude of approximately one-half, one, two, three, or four amperes.

The current adjuster 22 finely adjusts a drive amplitude of the drive current 12A that is directed to the device 12. The design of the current adjuster 22 can be varied pursuant to the teachings provided herein. For example, the current adjuster 22 can be designed to drain or deliver an adjuster current 22A (illustrated with a pulsed line) to the circuit. Stated in another fashion, the current adjuster 22 can be controlled by the control system 14 to selectively adjust an adjuster amplitude of the adjuster current 22A.

In certain implementations, it is desired to only drain current with the current adjuster 22 to avoid directing too much current to the device 12 that could damage the device 12 (e.g. overdrive the gain medium 26). In this example, the current adjuster 22 includes a current drain circuit that is controlled to selectively adjust the adjuster amplitude of the adjuster current 22A. In the circuit of FIG. 1, the drive amplitude of the drive current 12A is equal to the source amplitude of the source current 40A minus the adjuster amplitude of the adjuster current 22A. Thus, adjuster amplitude can be finely controlled to precisely control the drive amplitude of the drive current 12A without changing the source amplitude of the source current 40A. Stated in another fashion, the drive current 12A is equal to the source current 40A minus the drain current 22A. Thus, the current adjuster 22 can be controlled to adjust the drain current 22A, and thus adjust the drive current 12A to the device 12 without adjusting (independent of) the power source 40.

The current adjuster 22 can be proportional current drain in which the amount of current drain is proportional to a signal 42 (illustrated with an arrow) from the control system 14. As provided above, the device controller 16 is uniquely designed with the current adjuster 22 that rapidly, accurately, and selectively controls, tunes, and/or modulates the drive current 12A directed to the laser 12 to rapidly, accurately, and selectively control, tune, and/or modulate the center wavelength of illumination beam 20.

It should be noted that the drive current 12A in the gain medium 26 generates heat. Generally speaking, more drive current 12A results in more heat generation, while less drive current 12A results in less heat generation in the gain medium 26. Thus, the current adjuster 22 can rapidly make slight adjustments to the drive current 12A to rapidly make slight adjustments to the temperature of the gain medium 26. Further, as discussed above, changes in temperature result in changes in the index of refraction, changes in the effective optical path length, and changes to the center wavelength of the illumination beam 20. Thus, the current adjuster 22 can rapidly make slight adjustments to the drive current 12A to rapidly make slight adjustments to wavelength of the illumination beam 20. This design allows for the rapid modulation of the center wavelength of the illumination level on a sub-wavelength level.

In one non-exclusive implementation, the current adjuster 22 includes a bipolar transistor, or other type of transistor. However, other designs are possible. For example, the current adjuster 22 can be designed to include a simple MOSFET current source, a current mirror, and/or op-amp based current sources.

The frequency and magnitude in which the current adjuster 22 can be controlled to modulate the drive current 12A can be varied according to the design of the device 12 and its desired behavior. As a non-exclusive example, the current adjuster 22 can be controlled so that the drain current 22A selectively varies between zero and ten percent of the source current 40A to achieve small thermal temperature shifts in the gain medium 26. As alternative, non-exclusive examples, the current adjuster 22 can be designed to have a high frequency response, such as fifty, one hundred, two hundred, or three hundred megahertz. These designs allow for high frequency, fast drive current 12A and wavelength modulation.

Further, as alternative, non-exclusive examples, the current adjuster 22 can be controlled so that (i) the drain current 22A selectively varies between at least approximately zero and one hundred percent of the source current 40A; (ii) the drain current 22A selectively varies between at least approximately zero and twenty percent of the source current 40A; (iii) the drain current 22A selectively varies between at least approximately zero and ten percent of the source current 40A; (iv) the drain current 22A selectively varies between at least approximately zero and five percent of the source current 40A; (v) the drive current 12A selectively varies at least between approximately zero and one percent of the source current 40A; or (vi) the drive current 12A selectively varies at least between approximately zero and 0.1 percent.

For the implementation in which the device 12 includes the quantum cascade gain medium 26, the current adjuster 22 can be controlled so that (i) the drain current 22A selectively varies between at least zero and one hundred microamps; (ii) the drain current 22A selectively varies between at least zero and one milliamp; (iii) the drain current 22A selectively varies between at least zero and ten milliamps; (iv) the drain current 22A selectively varies between at least zero and one hundred milliamps; (v) the drain current 22A selectively varies between at least zero and two hundred milliamps; and/or (vi) the drain current 22A selectively varies between at least zero and five hundred milliamps.

The amount of change in the response of the device 12 to the changes in the drive current 12A will also depend upon the type of device 12. For the implementation in which the device 12 includes the quantum cascade gain medium 26, the current adjuster 22 can be controlled so that (i) the illumination beam 20 is selectively adjusted between at least zero and 0.1 wavenumbers; (ii) the illumination beam 20 is selectively adjusted between at least zero and 0.01 wavenumber; (iii) the illumination beam 20 is selectively adjusted between at least zero and 0.001 wavenumber; (iv) the illumination beam 20 is selectively adjusted between at least zero and 0.0001 wavenumber; or (v) the illumination beam 20 is selectively adjusted between at least zero and 0.00001 wavenumber. Stated differently, in alternative, non-exclusive examples, the current adjuster 22 can be used (e.g. like a knob) to make adjustments of at least approximately 0.1, 0.01, 0.001, 0.0001, or 0.00001 wavenumbers to the illumination beam 20.

It should be noted that the current adjuster 22 can be used for any frequency of source current 40A, including a direct current. Further, the drive current 12A is varied (finely tuned) without varying the source current 40A.

Additionally, it should be noted that the current adjuster 22 can be made as a relatively small circuit, and as a result thereof, the current adjuster 22 can be positioned in close proximity to the device 12. For example, in FIG. 2, the current adjuster 22 can be positioned in close proximity to the gain medium 26.

For the implementation in which the current adjuster 22 is a current dump, the current adjuster 22 is diverting the adjuster current 22A from going to the device 12. As a result thereof, the drive current 12A will be less and the device 12 will generate less heat. As provided herein, this thermal modulation is used to modulate the center wavelength of the illumination beam 20.

For the specific design in FIG. 2, the reduced heat generated by the gain medium 26 will result in slightly less heat being transferred to the thermal mount 34. However, this relatively small amount of heat difference may not exceed the noise level of the thermal controller 36.

In a non-exclusive implementation, the current adjuster 22 can be in thermal communication with and mounted directly on the thermal mount 34, and the temperature of the current adjuster 22 can also be controlled. With this design, the heat generated by the current adjuster 22 is transferred to the thermal mount 34, and compensates for the reduced heat generated by the gain medium 26. This results in an aggregate heat transferred to the thermal mount 34 from the current adjuster 22 and the gain medium 26 to be substantially constant, regardless of the magnitude of the adjuster current 22A.

With reference to FIG. 2, the laser 12 can also include a beam splitter 44 that directs a beam portion 45 (illustrated with a dashed arrow) of the illumination beam 20 at a wavelength sensor 46 which measures that wavelength of the illumination beam 20. This design allows for closed loop control of the wavelength selective element 32 and the current adjuster 22 to precisely control the center wavelength of the illumination beam. Alternatively, or additionally, the laser 12 can be calibrated at the factory.

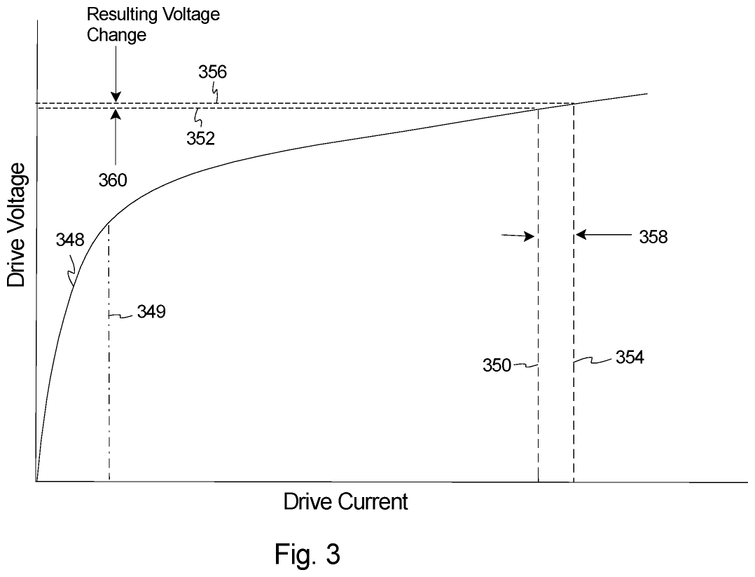

FIG. 3 is a graph that includes a curve 348 that illustrates the relationship of current versus voltage for a quantum cascade gain medium. The curve 348 is relatively steep at low currents and is relatively flat at higher currents. A threshold current 349 required for operating the gain medium is illustrated in FIG. 3. The threshold current 349 occurs in the curve above the point where this curve rolls over from vertical to more horizontal. The curve 348 is relatively flat for currents higher than the threshold current 349.

As illustrated therein, at low currents, small changes in the drive current to the quantum cascade gain medium results in large changes in drive voltage across the gain medium. In contrast, at higher currents (above the threshold current 349), small changes in drive current to the quantum cascade gain medium results in very small changes in drive voltage across the gain medium.

In FIG. 3, long dashed line 350 represents a first drive current that is directed to the quantum cascade gain medium, and short dashed line 352 represents the resulting first drive voltage across the quantum cascade gain medium. Similarly, long dashed line 354 represents a second drive current that is directed to the quantum cascade gain medium, and short dashed line 356 represents the resulting second drive voltage across the quantum cascade gain medium. In this non-exclusive example, the second drive current 354 is greater than the first drive current 350, and the second drive voltage 356 is greater than the first drive voltage 352.

Further, because of the characteristics of the quantum cascade gain medium, a relatively large change in current (delta current) 358 between first drive current 350 and the second drive current 354 results in a relatively small change in voltage (delta voltage) 360. As a non-exclusive example, for example, a delta current 358 of approximately one percent of the total current can result in a delta voltage 360 of approximately 0.1 percent of the total voltage.

As a result thereof, the current adjuster 22 can significantly adjust the drive current 12A while still only having an insignificant change on the voltage across the quantum cascade gain medium 26. In alternative, non-exclusive embodiments, the current adjuster 22 can adjust the drive current 12A while varying the voltage across the gain medium 26 less than approximately one, two, five, ten, twenty, fifty, or one hundred percent.

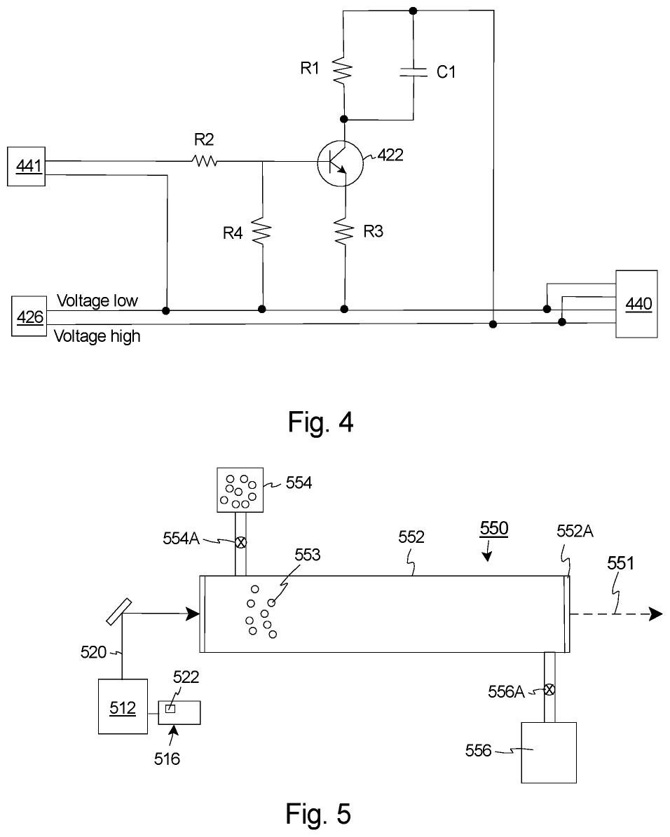

FIG. 4 is a simplified schematic of a non-exclusive implementation of the device controller that can accurately modulate the drive current to the device (e.g. the quantum cascade gain medium). In FIG. 4, the current driven power source 440 and the pulse generator 441 cooperate to direct the source current to the circuit to drive the gain medium 426. Further, the current adjuster 422 is electrically connected to the power source 440 and the gain medium 426 in parallel.

The circuit can include one or more resistors, capacitors and/or other components that improve the performance/behaviors of the system. In the non-exclusive implementation of FIG. 4 includes a first resistor R1, a second resistor R2, third resistor R3, a fourth resistor R4, and a capacitor C1. As a non-exclusive example, (i) the first resistor can have a resistance of approximately 1 K; (ii) the second resistor can have a resistance of approximately 50K; (iii) the third resistor can have a resistance of approximately 100K; (iv) the fourth resistor can have a resistance of approximately 100K; and (v) the first capacitor can have a capacitance of approximately 220 pF. However, other values are possible.

In FIG. 4, the current adjuster 422 is a low value current sink that selectively drains (diverts) current to selectively reduce the magnitude of the drive current directed to the gain medium 426. The input to the current adjuster 422 is driven by a high frequency clock source with a DC offset to bias the current adjuster 422 into its active region. The current adjuster 422 steals current and causes some current to bypass the gain medium 426. In most instances, since the magnitude of the current being shunted is much less than the operating current of the gain medium 426, the voltage across the gain medium 426 is not affected by the current shunt. Because there is no significant voltage changes, the frequency response of this circuit will be reasonably flat over a wide operating range from DC up to the f of the transistor of the current adjuster 422. Also, since this circuit can only can steal current from the gain medium 426, the maximum current driven into the gain medium 426 cannot be increased by driving this circuit.

FIG. 5 is a simplified schematic, non-exclusive implementation of a molecular laser assembly 550 that generates an output laser beam 551 (illustrated with long dashed line). The design of the molecular laser assembly 550 can be varied. In FIG. 5, the molecular laser assembly 550 includes a molecule container 552 that retains molecules 553 (illustrated with small circles), a molecule reservoir 554, a vacuum system 556, and a pump laser 512 that pumps the molecules 553 in the molecule container 552. Further, for example, the output laser beam 551 can be a terahertz radiation beam.

The molecule container 552 retains molecules 553 while they are being pumped with the pump laser 512. In the non-exclusive implementation of FIG. 5, the molecule container 552 is generally tube shaped and includes a mirror or partial reflector 552A on each end. However, other designs are possible.

The type of molecules 553 can be varied. For example, the molecules 553 can an infrared-active molecules, such as carbon monoxide, carbonyl sulfide, Fluoromethane, or Ammonia. The molecules 553 can be liquid or a gas.

The molecule reservoir 554 supplies the molecules 553 to the molecule container 552. The molecule reservoir 554 can include a molecule valve 554A that is controlled to control flow.

The vacuum system 556 controls the pressure in the molecule container 552. The molecule reservoir 554 can include a vacuum valve 556A that is controlled to control the pressure.

The pump laser 512 generates the illumination beam 520 that optically pumps the molecules 553. The pump laser 512 can be similar to the laser 12 described above and illustrated in FIG. 2. For example, the pump laser 512 can be a quantum cascade laser that generates an infrared illumination beam 520 that pumps the molecules 553 to generate the output laser beam 551.

As provided herein, due primarily to the Doppler shifts associated with the thermal motion of the molecules 553, the absorption full width at half maximum (“FWHM”) is much broader (by a factor of about 10⁶ to 10⁷) than the instantaneous linewidth of the quantum cascade laser 512. The static laser 512 therefore excites only a portion of the molecules 553 illuminated by the illumination beam 520 because of the narrow linewidth of the illumination beam 520. Accordingly, to improve pumping efficiency and output power of the output laser beam 551, the wavelength of the illumination may be rapidly modulated to excite more Doppler distribution (i.e., distribution of molecular velocities as projected onto the pump laser axis). For best effect, the wavelength modulation should occur within a time equal to or less than the mean collision time of the molecules.

As provided herein, the pump laser 512 can include a device controller 516 having a current adjuster 522 that is similar to the corresponding component described above. In this design, the current adjuster 522 is controlled to rapidly, accurately, and selectively control, tune, and/or modulate the drive current to the pump laser 512 to rapidly modulate the wavelength of the pump 520. This rapid modulation effectively broadens the linewidth of the illumination beam 520 to excite more of the molecules 553 and increase the power of the output laser beam 551.

While the particular systems as shown and disclosed herein is fully capable of obtaining the objects and providing the advantages herein before stated, it is to be understood that it is merely illustrative of the presently preferred embodiments of the invention and that no limitations are intended to the details of construction or design herein shown other than as described in the appended claims.

What is claimed is:

1. A device controller for directing a drive current to a device, the device controller comprising:
a current driven power source that is electrically connected to the device; and
a current adjuster electrically connected to the power source in parallel to the device, the current adjuster selectively adjusting the drive current directed to the device.

2. The device controller of claim 1 wherein the power source generates a source current, and the current adjuster selectively drains current to selectively adjust the drive current to the device.

3. The device controller of claim 1 wherein the current adjuster includes a bipolar transistor.

4. The device controller of claim 1 wherein the power source generates a source current, and the current adjuster selectively adjusts a drain current to selectively adjust the drive current to the device.

5. The device controller of claim 4 wherein the current adjuster adjusts the drain current to selectively vary between zero and twenty percent of the source current.

6. The device controller of claim 4 wherein the current adjuster adjusts the drain current to selectively vary between zero and ten percent of the source current.

7. The device controller of claim 1 wherein the power source includes a pulse generator and the power source directs current to the device in a pulsed fashion.

8. A laser assembly comprising a device that includes a laser, and the device controller of claim 1 that directs the drive current to the laser to generate an illumination beam.

9. The laser assembly of claim 8 wherein the laser includes a quantum cascade gain medium, and wherein the current adjuster selectively adjusts the drive current to the gain medium to selectively adjust a wavelength of the illumination beam.

10. The laser assembly of claim 8 wherein the laser includes a quantum cascade gain medium, and wherein the current adjuster selectively adjusts the drive current to the gain medium to effectively adjust a linewidth of the illumination beam.

11. The laser assembly of claim 8 wherein the laser includes a quantum cascade gain medium, and wherein the current adjuster selectively adjusts the drive current to the gain medium to modulate across a mode-hop.

12. The laser assembly of claim 8 wherein the laser includes a quantum cascade gain medium, and wherein the current adjuster electrically selectively drains current to modulate the drive current to the gain medium to selectively modulate a wavelength of the illumination beam.

13. The laser assembly of claim 8 wherein the laser includes (i) a quantum cascade gain medium, (ii) a thermal mount that is thermally connected to the quantum cascade gain medium, and (iii) a thermal controller that controls the temperature of the thermal mount.

14. The laser assembly of claim 8 wherein the laser includes (i) a quantum cascade gain medium, (ii) a thermal mount that is thermally connected to the quantum cascade gain medium and the current adjuster, and (iii) a thermal controller that controls the temperature of the thermal mount.

15. The laser assembly of claim 8 wherein the laser includes (i) a quantum cascade gain medium that generates the illumination beam; and (ii) a wavelength selective element that is controllable to make relatively coarse adjustments to a wavelength of the illumination beam; and wherein the current adjuster selectively adjusts the drive current to the gain medium to selectively finely adjust the wavelength of the illumination beam.

16. The laser assembly of claim 15 wherein the current adjuster selectively adjusts the drive current to the gain medium to selectively finely adjust the illumination beam between 0 and 0.1 wavenumbers.

17. The laser assembly of claim 15 wherein the current adjuster selectively adjusts the drive current to the gain medium to selectively finely adjust the illumination beam between 0 and 0.01 wavenumbers.

18. A molecular laser assembly comprising a molecule container that retains the molecules, and the laser assembly of claim 8 that directs the illumination beam into the molecule container to pump the molecules.

19. A laser assembly for generating an illumination beam, the laser assembly comprising:
a quantum cascade gain medium that generates the illumination beam;
a wavelength selective element that is controllable to make relatively coarse adjusts to a wavelength of the illumination beam; and
a device controller for directing a drive current to the gain medium, the device controller including (i) a current driven power source that is electrically connected to the gain medium, and (ii) a current adjuster electrically connected to the power source in parallel to the gain medium, the current adjuster being controllable to selectively adjust the drive current directed to the gain medium to finely adjust the wavelength of the illumination beam.

20. A method for directing a drive current to a device comprising:
electrically connecting a current driven power source to the device;
electrically connecting a current adjuster to the power source in parallel to the device; and
selectively adjusting the drive current directed to the device with the current adjuster.

21. The method of claim 20 wherein the power source generates a source current, and wherein selectively adjusting includes selectively draining current to selectively adjust the drive current to the device.

22. The method of claim 21 wherein selectively adjusting includes adjusting the drain current to selectively vary between zero and twenty percent of the source current.

23. The method of claim 21 wherein selectively adjusting includes adjusting the drain current to selectively vary between zero and ten percent of the source current.
